(19) United States
(12) Patent Application Publication
(10) Pub. No.: US 2026/0344268 A1
(43) Pub. Date: Oct. 29, 2026

(54) Display Device

(71) Applicant: LG Display Co., Ltd., Seoul (KR)

(72) Inventors: Hwa-Youl Lee, Paju-si (KR); Jae-Chul Hwang, Paju-si (KR); Byong-Hoo Kim, Paju-si (KR); Jae-Bin Song, Paju-si (KR)

(21) Appl. No.: 19/653,940

(22) Filed: Apr. 21, 2026

(30) Foreign Application Priority Data
Apr. 25, 2025 (KR) 10-2025-0054452

(51) Int. Cl. H10K 59/80; H10H 20/855; H10H 29/37; H10H 29/855; H10K 59/122

(52) U.S. Cl. CPC H10K 59/879; H10H 20/855; H10H 29/37; H10H 29/8552; H10K 59/122; H10K 59/8792

(57) ABSTRACT

A display device includes a substrate having an emission area and a non-emission area; a thin film transistor over the substrate and including a gate electrode, an active layer, a source electrode, and a drain electrode; a light-emitting diode in the emission area over the thin film transistor and including a first electrode, a light-emitting layer, and a second electrode; a bank in the non-emission area over the thin film transistor and disposed between the first electrode and the light-emitting layer; a control pattern over the light-emitting diode and the bank and corresponding to the emission area; and a lens over the control pattern and corresponding to the emission area, wherein the control pattern corresponds to the lens one-to-one and forms a step under the lens.

### CROSS-REFERENCE TO RELATED APPLICATIONS

This application claims priority under 35 U.S.C. § 119(a) to Republic of Korea Patent Application No. 10-2025-0054452, filed on Apr. 25, 2025, the entire contents of which are hereby expressly incorporated by reference into the present application.

### TECHNICAL FIELD

The present disclosure relates to a display device, and more particularly, to a display device capable of selectively limiting a viewing angle.

### BACKGROUND

As the information society progresses, demand for different types of display devices increases, and flat panel display devices (FPD) such as liquid crystal display devices (LCD) and organic light-emitting diode display devices (OLED) have been developed and applied to various fields.

Among the flat panel display devices, organic light-emitting diode display devices, which are also referred to as organic electroluminescent display devices, emit light due to the radiative recombination of an exciton. The exciton is formed from an electron and a hole by injecting charges into a light-emitting layer between a cathode for injecting electrons and an anode for injecting holes in a light-emitting diode.

The organic light-emitting diode display device can be formed over a flexible substrate, such as plastic, and offers various advantages and improved properties. For instance, because it is self-luminous, the organic light-emitting diode display device has an excellent contrast ratio and an ultra-thin thickness, and has a response time of several micro seconds. As such, there are advantages in displaying moving images and videos without delays using the organic light-emitting diode display device.

Additionally, the organic light-emitting diode display device has a wide viewing angle and is stable under low temperatures. Further, since the organic light-emitting diode display device is generally driven by a low voltage of direct current (DC) (e.g., 5V to 15V), it is easy to design and manufacture the driving circuits of the organic light-emitting display device.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

Although there is no limit to the viewing angle of the organic light-emitting diode display device, it has recently been desirable to limit the viewing angle for reasons of privacy protection and information protection.

For example, devices such as automated teller machine (ATM) of banking institutions, car navigation systems, laptops, and tablet PCs require limitations of viewing angles in the left, right, up, and down directions for privacy protection.

Accordingly, embodiments of the present disclosure are directed to a display device that substantially obviates one or more of the problems due to limitations and disadvantages of the related art.

An aspect of the present disclosure is to provide a display device capable of selectively limiting the viewing angle.

Another aspect of the present disclosure is to provide a display device capable of improving the reliability.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device includes a substrate having an emission area and a non-emission area; a thin film transistor over the substrate and including a gate electrode, an active layer, a source electrode, and a drain electrode; a light-emitting diode in the emission area over the thin film transistor and including a first electrode, a light-emitting layer, and a second electrode; a bank in the non-emission area over the thin film transistor and disposed between the first electrode and the light-emitting layer; a control pattern over the light-emitting diode and the bank and corresponding to the emission area; and a lens over the control pattern and corresponding to the emission area, wherein the control pattern corresponds to the lens one-to-one and forms a step under the lens.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure, and which are incorporated in and constitute a part of this application, illustrate embodiments of the disclosure and together with the description serve to explain various principles of the disclosure. In the drawings:

FIG. 1 is a schematic plan view of a display device according to an embodiment of the present disclosure;

FIG. 2 is a cross-sectional view of a display device according to the embodiment of the present disclosure;

FIG. 3 is a schematic enlarged cross-sectional view of a display device according to the embodiment of the present disclosure;

FIGS. 4A to 4C are schematic enlarged cross-sectional views of a display device in steps of forming a lens and a step of performing a reliability test according to the embodiment of the present disclosure;

FIGS. 5A to 5C are schematic enlarged cross-sectional views of a display device in steps of forming a lens and a step of performing a reliability test according to a comparative example;

FIG. 6 is a schematic enlarged cross-sectional view of a display device according to another embodiment of the present disclosure; and

FIG. 7 is a schematic enlarged cross-sectional view of a display device according to yet another embodiment of the present disclosure.

### DETAILED DESCRIPTION

The terms used in the embodiments of the present disclosure have been selected from widely used, current terms, taking functionality into consideration. However, these terms may vary depending on the intentions of those skilled in the art, precedents, the emergence of new technologies, etc. In certain cases, the applicant may arbitrarily select terms, in which case their meanings will be described in detail in the relevant description. Therefore, the terms used in the present disclosure should be defined not simply based on their names, but based on their meaning and the overall context of the present disclosure.

When a part throughout the present disclosure is said to “include” a component, unless otherwise specifically stated, this does not exclude other components but rather implies the inclusion of other components.

The expression “at least one of a, b, and c” described throughout the present disclosure may encompass “a alone,” “b alone,” “c alone,” “a and b,” “a and c,” “b and c,” or “all a, b, and c.” The advantages and features of the present disclosure, and methods for achieving them, will become apparent with reference to the embodiments described in detail below, along with the accompanying drawings.

The shapes, areas, ratios, angles, numbers, etc. disclosed in the drawings used to explain the embodiments herein are illustrative and are not limited to the embodiments illustrated. When describing the embodiments, detailed descriptions of related known technologies are omitted if they are deemed to unnecessarily obscure the gist of the embodiments.

When used herein, terms such as “include,” “have,” and “consist of” may be used to indicate that additional components may be added. When a component is expressed in the singular, the plural is also included unless otherwise explicitly stated. Furthermore, when interpreting a component, even if not explicitly stated, the error range is assumed to be included.

When describing a positional relationship, for example, when describing the positional relationship between two parts using terms such as “on,” “above,” “below,” or “next to,” one or more other components may be located between the two parts. When an element or layer is referred to as “on” another element or layer, this includes both cases where the other element is directly on top of the other element or where another layer or element is interposed.

Although terms such as “first” and “second” are used to describe various components, these components are not limited by these terms. These terms are used solely to distinguish one component from another. Therefore, a “first” component referred to below may also be a “second” component within the technical scope of the present disclosure.

The area, length, or thickness of each component described in the present disclosure is illustrated for convenience of explanation, and the present disclosure is not necessarily limited to the area and thickness of the illustrated components.

The features of each of the various embodiments of the present disclosure may be partially or fully combined or combined with each other, enabling various technical interlocking and operation. Each embodiment may be implemented independently of the other or may be implemented together in a related manner.

The terms described below are defined based on their functions in the implementation of the present disclosure and may vary depending on the intent or custom of the user or operator. Therefore, their definitions should be based on the overall content of the present disclosure.

Unless otherwise specified, the transistors constituting the pixel circuit of the present disclosure may include one or more of an oxide thin film transistor (Oxide TFT), an amorphous silicon TFT (a-Si TFT), or a low-temperature polysilicon TFT (LTPS TFT).

The following embodiments are described with a focus on an organic light-emitting diode (OLED) display. However, embodiments of the present disclosure are not limited to organic light-emitting diode (OLED) display devices and may also be applied to inorganic light-emitting diode display devices containing inorganic light-emitting materials and micro LED display devices. For example, embodiments of the present disclosure may also be applied to quantum dot (QD) display devices. That is, the display device of the present disclosure may be a light-emitting display device including a light-emitting diode, a quantum dot light-emitting display device including a quantum dot light-emitting diode, or a micro LED display device including a micro-LED.

Terms such as “first,” “second,” and “third” are used to distinguish configurations by embodiment, and the embodiments are not limited to these terms. Therefore, the same term may refer to different configurations depending on the embodiment.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Hereinafter, examples of embodiments of the present disclosure will be described in detail with reference to accompanying drawings.

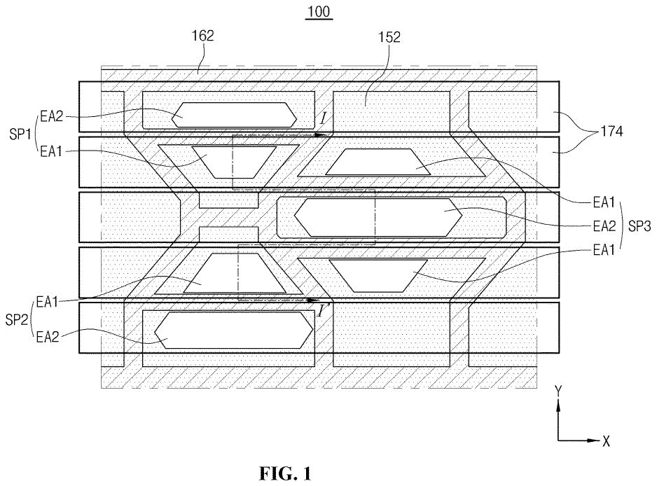

FIG. 1 is a schematic plan view of a display device according to an embodiment of the present disclosure.

As shown in FIG. 1, the display device 100 according to an embodiment of the present disclosure can include a plurality of pixels, and each pixel can include a plurality of sub-pixels SP1, SP2, and SP3. For example, each pixel can include first, second, and third sub-pixels SP1, SP2, and SP3, and the first, second, and third sub-pixels SP1, SP2, and SP3 can be red, green, and blue sub-pixels, respectively.

The third sub-pixel SP3 can be disposed adjacent to the first and second sub-pixels SP1 and SP2 in a first direction X. The first sub-pixel SP1 and the second sub-pixel SP2 can be disposed adjacent to each other in a second direction Y crossing the first direction X.

Accordingly, the third sub-pixel SP3 can be disposed between the first sub-pixels SP1 adjacent in the first direction X and between the second sub-pixels SP2 adjacent in the first direction X. The first sub-pixel SP1 and the second sub-pixel SP2 can be disposed between the third sub-pixels SP3 adjacent in the first direction X.

In addition, the second sub-pixel SP2 can be disposed between the first sub-pixels SP1 adjacent in the second direction Y, and the first sub-pixel SP1 can be disposed between the second sub-pixels SP2 adjacent in the second direction Y.

However, embodiments of the present disclosure are not limited thereto. In other embodiments, the arrangement of the first, second, and third sub-pixels SP1, SP2, and SP3 can vary.

Each of the first, second, and third sub-pixels SP1, SP2, and SP3 can include at least one first emission area EA1 and at least one second emission area EA2. For example, each of the first sub-pixel SP1 and the second sub-pixel SP2 can include one first emission area EA1 and one second emission area EA2, and the third sub-pixel SP3 can include two first emission areas EA1 and one second emission area EA2.

Here, the first emission areas EA1 of the first and second sub-pixels SP1 and SP2 can be disposed between the second emission areas EA2 of the first and second sub-pixels SP1 and SP2 in the second direction Y, and the second emission area EA2 of the third sub-pixel SP3 can be disposed between the two first emission areas EA1 of the third sub-pixel SP3 in the second direction Y. In addition, the first emission area EA1 of the first sub-pixel SP1 can be disposed adjacent to one first emission area EA1 of the third sub-pixel SP3 in the first direction X, and the first emission area EA1 of the second sub-pixel SP2 can be disposed adjacent to the other first emission area EA1 of the third sub-pixel SP3 in the first direction X.

However, embodiments of the present disclosure are not limited thereto. In other embodiments, the first, second, and third sub-pixels SP1, SP2, and SP3 can include the same number of first emission areas EA1 or different numbers of first emission areas EA1.

The first emission area EA1 and the second emission area EA2 can have different areas. In this case, the area of the second emission area EA2 can be larger than the area of the first emission area EA1. However, embodiments of the present disclosure are not limited thereto. In other embodiments, the first emission area EA1 and the second emission area EA2 can have the same area, or the area of the first emission area EA1 can be larger than the area of the second emission area EA2.

The first emission areas EA1 of the first, second, and third sub-pixels SP1, SP2, and SP3 can have a diamond shape, and the second emission areas EA2 of the first, second, and third sub-pixels SP1, SP2, and SP3 can have a hexagonal shape. However, embodiments of the present disclosure are not limited thereto. In other embodiments, the first emission areas EA1 and the second emission areas EA2 can have a polygonal shape excluding the diamond shape and the hexagonal shape, a circular shape, or an oval shape.

Lenses 174 can be provided to correspond to the first and second emission areas EA1 and EA2, respectively. The lenses 174 can be semi-cylindrical lenses which extend in the first direction X and are spaced apart from each other. In this case, the first emission area EA1 and the second emission area EA2 can correspond to different lenses 174.

Specifically, one lens 174 can be provided to correspond to the first emission area EA1 of the first sub-pixel SP1 and the first emission area EA1 of the third sub-pixel SP3 adjacent to each other in the first direction X, another lens 174 can be provided to correspond to the first emission area EA1 of the second sub-pixel SP2 and the first emission area EA1 of the third sub-pixel SP3 adjacent to each other in the first direction X, and other lenses 174 can be provided to correspond to the second emission areas EA2 of the first, second, and third sub-pixels SP1, SP2, and SP3, respectively. Accordingly, five lenses 174 can be provided to correspond to the first, second, and third sub-pixels SP1, SP2, and SP3 of one pixel. However, embodiments of the present disclosure are not limited thereto, and the number and arrangement of the lenses 174 can vary.

Meanwhile, a black matrix 152 and a sensor layer 162 can be provided between the first and second emission areas EA1 and EA2 and the lenses 174.

The black matrix 152 and the sensor layer 162 can act as a light-blocking layer that blocks light and can be disposed between adjacent sub-pixels SP1, SP2, and SP3 and between adjacent first and second emission areas EA1 and EA2.

The sensor layer 162 can extend in the first direction X and/or the second direction Y, thereby forming a sensing electrode. The sensing electrode can include a transmitter electrode and a receiver electrode, and a touch input can be detected from the amount of variation in a capacitance between the transmitter electrode and the receiver electrode.

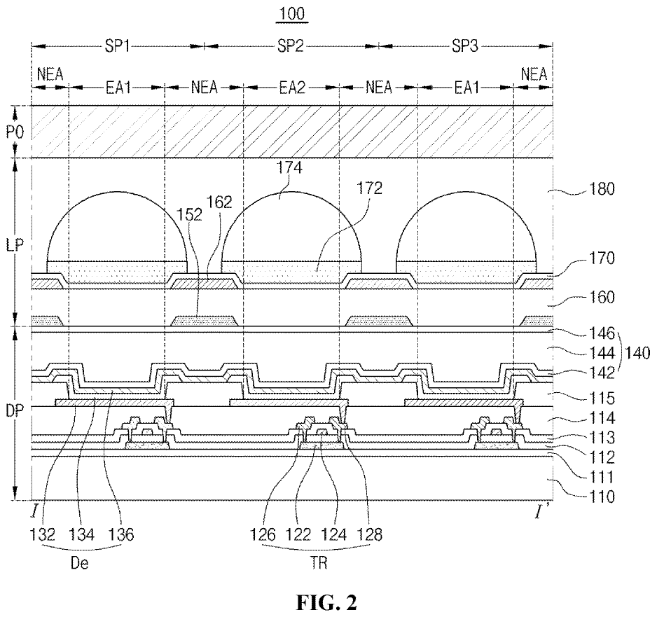

A cross-sectional configuration of the display device according to an embodiment of the present disclosure will be described with reference to FIG. 2.

FIG. 2 is a cross-sectional view of a display device according to the embodiment of the present disclosure and shows a cross-section corresponding to line I-I′ of FIG. 1.

As shown in FIG. 2, the display device 100 according to the embodiment of the present disclosure can include a display panel DP, a light control panel LP, and a polarizing plate PO.

The display panel DP can include a plurality of sub-pixels SP1, SP2, and SP3, and each of the plurality of sub-pixels SP1, SP2, and SP3 can include an emission area EA1 and EA2 and a non-emission area NEA. A thin film transistor TR and a light-emitting diode De can be provide over a substrate 110 of the display panel DP, and the light-emitting diode De can be disposed to correspond to the emission area EA1 and EA2.

The light control panel LP can include the black matrix 152, the sensor layer 162, and the lens 174. Light emitted from the light-emitting diode De of the display panel DP can be output to the outside through the lens 174 of the light control panel LP to thereby be concentrated in a front direction, and viewing angles can be limited by the black matrix 152 and the sensor layer 162.

Meanwhile, the polarizing plate PO can prevent or reduce the external light from being reflected by the display panel DP to be output to the outside.

Specifically, the substrate 110 of the display panel DP can be formed of a transparent insulating material and, for example, can be a glass substrate or a plastic substrate. Polyimide can be used for the plastic substrate, and the plastic substrate can have a stacked structure including at least one polyimide layer and at least one inorganic layer. However, embodiments of the present disclosure are not limited thereto.

A buffer layer 111 can be provided over the substrate 110. The buffer layer 111 can be disposed substantially all over the substrate 110. The buffer layer 111 can be formed as a single layer or multiple layers of an inorganic insulating material. The inorganic insulating material of the buffer layer 111 can include silicon nitride (SiNₓ), silicon oxide (SiOₓ), or silicon oxynitride (SiON).

A semiconductor layer 122 can be provided over the buffer layer 111. The semiconductor layer 122 can include a channel region at its central part and source and drain regions at both sides of the channel region. The semiconductor layer 122 can be formed of an oxide semiconductor material. Alternatively, the semiconductor layer 122 can be formed of polycrystalline silicon, and in this case, both end parts of the semiconductor layer 122 can be doped with impurities.

Meanwhile, although not shown in the figure, a light-shielding pattern can be further provided between the substrate 110 and the buffer layer 111 and can be formed of a conductive material such as metal. The light-shielding pattern can overlap the semiconductor layer 122, and can block light incident on the semiconductor layer 122 and reduce or prevent or reduce the semiconductor layer 122 from deteriorating due to the light.

A gate insulation layer 112 can be provided over the semiconductor layer 122. The gate insulation layer 112 can be disposed substantially all over the substrate 110. The gate insulation layer 112 can be formed as a single layer or multiple layers of an inorganic insulating material. The inorganic insulating material of the gate insulation layer 112 can include silicon nitride (SiNₓ), silicon oxide (SiOₓ), or silicon oxynitride (SiON).

A gate electrode 124 can be provided over the gate insulation layer 112. The gate electrode 124 can overlap the semiconductor layer 122 and can be disposed to correspond to the central part of the semiconductor layer 122. Accordingly, the gate electrode 124 can overlap the channel region of the semiconductor layer 122.

The gate electrode 124 can be formed of a conductive material such as metal. For example, the gate electrode 124 can be formed of one or more of: aluminum (Al), copper (Cu), molybdenum (Mo), titanium (Ti), chromium (Cr), nickel (Ni), tungsten (W), and an alloy thereof. The gate electrode 124 can have a single-layered structure or a multiple-layered structure.

Although not shown in the figure, a first capacitor electrode can be further provided over the gate insulation layer 112 and can be formed of the same material as the gate electrode 124. The first capacitor electrode can be spaced apart from the semiconductor layer 122 and the light-shielding pattern.

An interlayer insulation layer 113 can be provided over the gate electrode 124. The interlayer insulation layer 113 can be disposed substantially all over the substrate 110. The interlayer insulation layer 113 can be formed as a single layer or multiple layers of an inorganic insulating material. The inorganic insulating material of the interlayer insulation layer 113 can include silicon nitride (SiNₓ), silicon oxide (SiOₓ), or silicon oxynitride (SiON).

Source and drain electrodes 126 and 128 can be provided over the interlayer insulation layer 113. The source and drain electrodes 126 and 128 can be spaced apart from each other with the gate electrode 124 positioned therebetween and can be in contact with the both end parts of the semiconductor layer 122 through contact holes provided in the interlayer insulation layer 113 and the gate insulation layer 112.

The source and drain electrodes 126 and 128 can be formed of a conductive material such as metal. For example, the source and drain electrodes 126 and 128 can be formed of one or more of: aluminum (Al), copper (Cu), molybdenum (Mo), titanium (Ti), chromium (Cr), nickel (Ni), tungsten (W), and an alloy thereof. The source and drain electrodes 126 and 128 can have a single-layered structure or a multiple-layered structure.

The source and drain electrodes 126 and 128, the gate electrode 124, and the semiconductor layer 122 can form a thin film transistor TR.

Meanwhile, one or more transistors electrically connected to the thin film transistor TR can be further provided over the substrate 110. The transistor can have substantially the same configuration as the thin film transistor TR.

However, embodiments of the present disclosure are not limited thereto. Alternatively, the transistor can have a different configuration from the thin film transistor TR. For example, the thin film transistor TR can be an oxide semiconductor thin film transistor using an oxide semiconductor material as the semiconductor layer 122, and the transistor can be a low temperature polycrystalline silicon thin film transistor using a polycrystalline semiconductor material as a semiconductor layer.

In addition, a second capacitor electrode can be further provided over the interlayer insulation layer 113 and can be formed of the same material as the source electrode 126 and the drain electrode 128. The second capacitor electrode can overlap the first capacitor electrode to thereby form a storage capacitor.

However, embodiments of the present disclosure are not limited thereto. In other embodiments, the second capacitor electrode can be provided on a different layer from the source electrode 126 and the drain electrode 128.

A planarization layer 114 can be provided over the source electrode 126 and the drain electrode 128. The planarization layer 114 can be disposed substantially all over the substrate 110. The planarization layer 114 can eliminate a step difference due to the layers thereunder and can have a substantially flat top surface. The planarization layer 114 can be formed of an organic insulating material such as photosensitive acrylic polymer (photo acryl).

A first electrode 132 can be provided over the planarization layer 114 and can be formed of a conductive material having relatively high work function. The first electrode 132 can be disposed to correspond to the emission area EA1 and EA2. In addition, the first electrode 132 can also be partially disposed in the non-emission area NEA.

The first electrode 132 can be electrically connected to the drain electrode 128. In this case, the first electrode 132 can be in direct contact with the drain electrode 128 through a contact hole provided in the planarization layer 114.

However, embodiments of the present disclosure are not limited thereto. In other embodiments, a connection electrode can be further provided between the drain electrode 128 and the first electrode 132. The first electrode 132 can be in direct contact with the connection electrode, and the connection electrode can be in direct contact with the drain electrode 128, so that the first electrode 132 can be electrically connected to the drain electrode 128 through the connection electrode.

For example, the first electrode 132 can include a transparent conductive material such as indium tin oxide (ITO) or indium zinc oxide (IZO) or can include titanium (Ti). However, embodiments of the present disclosure are not limited thereto.

Meanwhile, the first electrode 132 can have a multi-layered structure including a material with relatively high reflectance. For example, the first electrode 132 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank 115 of an organic insulating material can be provided over the first electrode 132. The bank 115 can be disposed to correspond to the non-emission area NEA. The bank 115 can overlap edges of the first electrode 132 and cover the edges of the first electrode 132. The bank 115 can expose a central portion of the first electrode 132. The bank 115 can cover the contact hole provided in the planarization layer 114.

The bank 115 can have an opening exposing the first electrode 132. The opening of the bank 115 can be disposed to correspond to the emission area EA1 and EA2. The emission area EA1 and EA2 can be defined by the bank 115 having the opening.

Meanwhile, although not shown in the figure, a spacer can be further provided on the bank 115 in the non-emission area NEA.

A light-emitting layer 134 can be provided over the first electrode 132 exposed by the bank 115. The light-emitting layer 134 can be disposed to correspond to the emission area EA1 and EA2. In addition, the light-emitting layer 134 can also be partially disposed in the non-emission area NEA.

The light-emitting layer 134 can emit one of red, green, and blue lights. For example, the light-emitting layer 134 of the first sub-pixel SP1 can emit red light, the light-emitting layer 134 of the second sub-pixel SP2 can emit green light, and the light-emitting layer 134 of the third sub-pixel SP3 can emit blue light.

The light-emitting layer 134 can include at least one hole auxiliary layer, at least one light-emitting material layer, and at least one electron auxiliary layer constituting one light-emitting unit.

The light-emitting material layer can include one of red, green, and blue luminescent materials. The luminescent material can be an organic luminescent material such as a phosphorescent compound or a fluorescent compound or can be an inorganic luminescent material such as a quantum dot.

The hole auxiliary layer can include at least one of a hole injection layer (HIL) and a hole transport layer (HTL). The electron auxiliary layer can include at least one of an electron injection layer (EIL) and an electron transport layer (ETL).

As shown in the figure, the light-emitting layer 134 can be disposed on the first electrode 132 exposed by the bank 115 and can be separated for each of the first, second, and third sub-pixels SP1, SP2, and SP3. In this case, the light-emitting layer 134 can partially contact top and side surfaces of the bank 115.

However, embodiments of the present disclosure are not limited thereto. In other embodiments, some of the light-emitting layer 134, for example, the light-emitting material layer can be disposed only on the first electrode 132, and the hole auxiliary layer and the electron auxiliary layer can be disposed substantially all over the substrate 110.

Alternatively, the light-emitting layer 134 can emit white light and can be provided on the top and side surfaces of the bank 115, so that the light-emitting layer 134 can be disposed substantially all over the substrate 110. In this case, the light-emitting layer 134 can include a plurality of light-emitting units emitting light of different colors and being stacked. Each stack can include at least one hole auxiliary layer, at least one light-emitting material layer, and at least one electron auxiliary layer.

For example, the light-emitting layer 134 can have a stack structure in which two or more light-emitting units emitting different colors are stacked, and a charge generation layer (CGL) can be provided between adjacent light-emitting units.

A second electrode 136 of a conductive material with relatively low work function can be provided over the light-emitting layer 134. The second electrode 136 can be disposed substantially all over the substrate 110.

The second electrode 136 can be formed of aluminum (Al), magnesium (Mg), silver (Ag), or an alloy thereof. In this case, the second electrode 136 can have a relatively thin thickness such that light from the light-emitting layer 134 can be transmitted therethrough. For example, the second electrode 136 can have a thickness of 5 nm to 10 nm, but embodiments of the present disclosure are not limited thereto.

Alternatively, the second electrode 136 can be formed of a transparent conductive material such as indium gallium oxide (IGO) or IZO.

The first electrode 132, the light-emitting layer 134, and the second electrode 136 can constitute the light-emitting diode De. Here, the first electrode 132 can serve as an anode, and the second electrode 136 can serve as a cathode. However, embodiments of the present disclosure are not limited thereto. In other embodiments, the first electrode 132 can serve as a cathode, and the second electrode 136 can serve as an anode.

An encapsulation layer 140 can be provided over the second electrode 136 and disposed substantially all over the substrate 110. The encapsulation layer 140 can protect the light-emitting diode De from external moisture or oxygen. The encapsulation layer 140 can have a multiple-layered structure including at least one inorganic layer and at least one organic layer.

For example, the encapsulation layer 140 can include first, second, and third encapsulation layers 142, 144, and 146. In this case, the second encapsulation layer 144 can be disposed between the first and third encapsulation layers 142 and 146. The first and third encapsulation layers 142 and 146 can be an inorganic layer. The second encapsulation layer 144 can be an organic layer and can be a layer covering particles that are generated during the manufacturing process.

Meanwhile, although not shown in the figure, a capping layer can be provided between the second electrode 136 and the encapsulation layer 140. The capping layer can be formed of an insulating material having a relatively high refractive index. The wavelength of light traveling along the capping layer can be amplified by surface plasma resonance. Thus, the intensity of the peak can be increased, thereby improving the light efficiency in the display device. For example, the capping layer can be formed as a single layer of an organic layer or an inorganic layer, or can be formed as organic/inorganic stacked layers.

Next, the light control panel LP can be provided over the encapsulation layer 140. The light control panel LP can include the black matrix 152, an intermediate insulation layer 160, the sensor layer 162, a passivation layer 170, a control pattern 172, the lens 174, and a protection layer 180.

Specifically, the black matrix 152 can be provided over the encapsulation layer 140. The black matrix 152 can be disposed to correspond to the non-emission area NEA and can overlap the bank 115. The black matrix 152 can have an opening corresponding to the emission area EA1 and EA2.

The width and area of the opening of the black matrix 152 can be greater than the width and area of the opening of the bank 115. That is, the width and area of the black matrix 152 can be smaller than the width and area of the bank 115. However, embodiments of the present disclosure are not limited thereto.

The black matrix 152 can be formed of a black resin absorbing light. For example, the black resin can include a black pigment and/or carbon black. However, embodiments of the present disclosure are not limited thereto.

Meanwhile, although not shown in the figure, a bridge electrode and at least one sensor buffer layer can be further provided between the encapsulation layer 140 and the black matrix 152. The bridge electrode can be formed of a conductive material such as metal, and the sensor buffer layer can be formed of an inorganic insulating material.

The bridge electrode can correspond to the non-emission area NEA and can overlap the black matrix 152. The bridge electrode can selectively contact a plurality of patterns of the sensor layer 162 and can connect the plurality of patterns of the sensor layer 162 in the first direction X and/or the second direction Y.

The intermediate insulation layer 160, which is a first sensor insulation layer, can be provided over the black matrix 152. The intermediate insulation layer 160 can be formed of an organic insulating material such as photosensitive acrylic polymer (photo acryl).

The sensor layer 162 can be provided over the intermediate insulation layer 160. The sensor layer 162 can act as a light-blocking layer that blocks light. The sensor layer 162 can correspond to the non-emission area NEA and can overlap the black matrix 152 and the bank 115. The sensor layer 162 can have an opening corresponding to the emission area EA1 and EA2.

The width and area of the opening of the sensor layer 162 can be greater than the width and area of the opening of the bank 115. That is, the width and area of the sensor layer 162 can be smaller than the width and area of the bank 115. In addition, the width and area of the opening of the sensor layer 162 can be substantially the same as the width and area of the opening of the black matrix 152. That is, the width and area of the sensor layer 162 can be substantially the same as the width and area of the black matrix 152.

However, embodiments of the present disclosure are not limited thereto. The width and area of each of the black matrix 152 and the sensor layer 162 can vary depending on the thickness of the intermediate insulation layer 160 and the area and/or structure of the emission area EA1 and EA2.

The sensor layer 162 can be formed of a conductive material such as metal. The sensor layer 162 can be formed of one or more of: aluminum (Al), copper (Cu), molybdenum (Mo), titanium (Ti), chromium (Cr), nickel (Ni), tungsten (W), and an alloy thereof. For example, the sensor layer 162 can have a single-layered structure or a multiple-layered structure.

The sensor layer 162 can include the plurality of patterns. The plurality of patterns of the sensor layer 162 can be selectively connected to each other through the bridge electrode in the first direction X and/or the second direction Y, thereby forming the sensing electrode.

The passivation layer 170, which is a second sensor insulation layer, can be provided over the sensor layer 162. The passivation layer 170 can be formed as a single layer or multiple layers of an inorganic insulating material. The inorganic insulating material of the passivation layer 170 can include silicon nitride (SiNₓ), silicon oxide (SiOₓ), or silicon oxynitride (SiON).

The control pattern 172 and the lens 174 can be sequentially provided over the passivation layer 170. The control pattern 172 and the lens 174 can be disposed to correspond to the emission area EA1 and EA2 and can correspond one-to-one. That is, the number of the control pattern 172 can be the same as the number of the lens 174.

The control pattern 172 and the lens 174 can have substantially the same planar shape. In this case, the width and area of the lens 174 can be the same as or smaller than the width and area of the control pattern 172.

In addition, the control pattern 172 and the lens 174 can be partially disposed in the non-emission area NEA. Accordingly, the control pattern 172 and the lens 174 can overlap the sensor layer 162, the black matrix 152, and the bank 115.

The control pattern 172 can limit the contact angle of the material of the lens 174, thereby improving the uniformity during formation of the lens 174 and preventing or reducing the shape deformation due to reflowing the material of the lens 174 in a high-temperature reliability environment. The control pattern 172 will be described in detail later.

The lens 174 can output light emitted from the light-emitting diode De at a specific angle, thereby increasing the front luminance. The lens 174 can have a relatively high refractive index. For example, the refractive index of the lens 174 can be greater than 1.5 and less than 1.8, and preferably, greater than 1.6 and less than 1.7. However, embodiments of the present disclosure are not limited thereto.

The lens 174 can be formed of an organic polymer. For example, the lens 174 can include an acrylate polymer, a biphenyl polymer, a phenyl sulfide polymer, a diphenyl fluorine polymer, or a carbazole polymer, but embodiments of the present disclosure are not limited thereto.

Then, the protection layer 180 can be provided over the lens 174 and can protect the lens 174. The protection layer 180 can be formed of an organic insulating material and can have a substantially flat top surface. The protection layer 180 can be formed of an organic insulating material such as photosensitive acrylic polymer (photo acryl), benzocyclobutene (BCB), polyimide (PI) or polyamide (PA), but embodiments of the present disclosure are not limited thereto.

The protection layer 180 can have a relatively low refractive index. The refractive index of the protection layer 180 can be smaller than the refractive index of the lens 174. For example, the refractive index of the protection layer 180 can be greater than 1.0 and less than 1.5. However, embodiments of the present disclosure are not limited thereto.

Meanwhile, a polarizing plate PO can be provided over the protection layer 180 of the light control panel LP. The polarizing plate PO can include a linear polarizing layer and a retardation layer. The retardation layer can be disposed between the protection layer 180 and the linear polarizing layer. The polarizing plate PO can change the polarizing state of the external light incident on the display panel DP, so that the external light can be prevented or reducing from being output to the outside after being reflected in the display panel DP.

As such, in the display device 100 according to the embodiment of the present disclosure, by providing the lens 174 to correspond to the emission area EA1 and EA2, light can be concentrated by the lens 174 and output to the outside in the front direction, and by providing the black matrix 152 and the sensor layer 162 to correspond to the non-emission area NEA, light toward the side direction can be blocked, and the light influence of adjacent sub-pixels SP1, SP2, and SP3 can be limited. Accordingly, the front luminance can be improved, and the viewing angle can be limited.

Here, if only one of the black matrix 152 and the sensor layer 162 is provided, the light toward the side direction cannot be entirely blocked, so that the viewing angle cannot be completely restricted. Therefore, the display device 100 according to the embodiment of the present disclosure can have a double light-blocking structure of the black matrix 152 and the sensor layer 162.

The display device 100 according to the embodiment of the present disclosure can be applied to a vehicle. In this case, since the display device 100 according to the embodiment of the present disclosure can have the narrow viewing angle in the vertical direction, that is, in the second direction Y, it is possible to prevent or reduce an image from being reflected by the windscreen or windshield of a vehicle and obstructing the driver's view.

Meanwhile, the lens 174 of the display device 100 according to the embodiment of the present disclosure can be formed through a thermal reflow process after forming a polymer pattern. The thermal reflow process can involve applying heat to the polymer pattern to impart fluidity and have a specific contact angle due to a difference in surface energy with respect to the underlying member.

However, since the polymer has a molecular weight in a certain range rather than a single molecular weight after curing, there is a variation in the glass transition temperature Tg and heat resistance according to each molecular weight level, and the lens 174 can be formed differently depending on the location when manufacturing a large-area display device.

In addition, a reliability environment with different temperature conditions can be required for each applied product, and if reflow is designed to occur at low temperatures, the shape of the lens 174, that is, the width and thickness of the lens 174, can be deformed in high-temperature environments, causing reliability problems. In particular, when applied to vehicles, reliability for a higher temperature environment can be required.

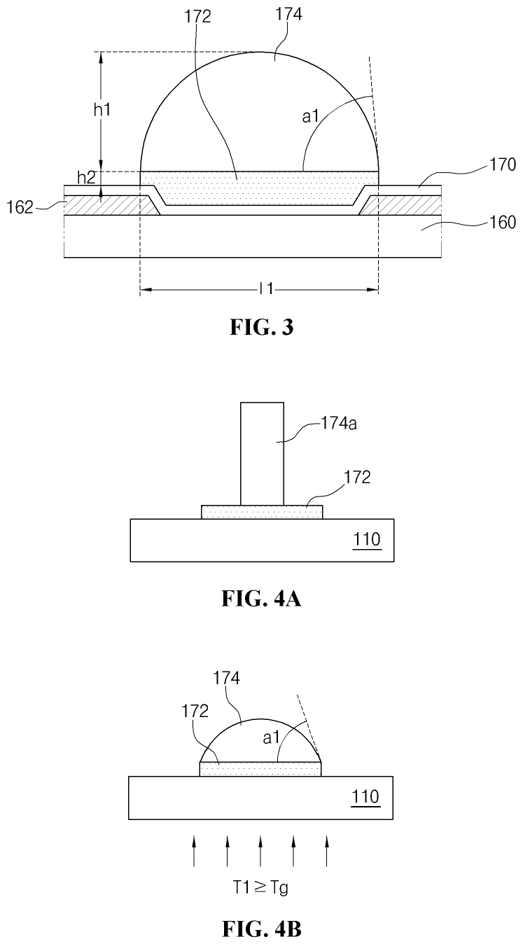

Accordingly, in the display device 100 according to the embodiment of the present disclosure, the control pattern 172 can be provided under the lens 174, that is, between the passivation layer 170 and the lens 174, in order to control the contact angle of the polymer material and limit the reflow area, and this will be described with reference to FIG. 3.

FIG. 3 is a schematic enlarged cross-sectional view of a display device according to the embodiment of the present disclosure and shows configurations corresponding to one lens. It will be described with reference to FIGS. 1 and 2.

In FIG. 3, the sensor layer 162 can be provided over the intermediate insulation layer 160, the passivation layer 170 can be provided over the sensor layer 162, and the control pattern 172 and the lens 174 can be sequentially provided over the passivation layer 170.

Here, the lens 174 can be disposed only on the control pattern 172 and can be spaced apart from the passivation layer 170 without contacting the passivation layer 170.

The width of the lens 174, that is, the chord length l1 can be equal to or smaller than the width of the control pattern 172. In addition, the thickness of the lens 174, that is, the arc height h1 can be smaller than the chord length l1. For example, the arc height h1 of the lens 174 can be about 7 μm~13 μm, and the chord length l1 of the lens 174 can be about 17 μm~23 μm. However, embodiments of the present disclosure are not limited thereto.

Meanwhile, the control pattern 172 can form a step greater than a predetermined level under the lens 174 to limit the contact angle of the material of the lens 174. That is, the control pattern 172 can have a step with respect to a top surface of the passivation layer 170. The step height h2 of the control pattern 172, preferably, can be 1μm or less. If the step height h2 of the control pattern 172 is greater than 1μm, the light emitted from the light-emitting diode De can be output without passing through the lens 174, resulting in a decrease in the front luminance.

By minimizing or reducing the difference between the surface energy of the control pattern 172 and the surface tension (surface energy) of the material of the lens 174, a relatively high contact angle a1 can be achieved. For example, the contact angle a1 of the lens 174 can be 70 to 80 degrees, but is not limited thereto.

In this case, to minimize or reduce the decrease in transmittance, it is preferable that the control pattern 172 has transmittance similar to that of the lens 174. That is, the transmittance of the control pattern 172 can be equal to or greater than the transmittance of the lens 174.

In addition, to prevent or reduce light emitted from the light-emitting diode De from being reflected at an interface between the control pattern 172 and the lens 174, the refractive index of the control pattern 172 can be equal to or greater than the refractive index of the lens 174. If the refractive index of the control pattern 172 is smaller than the refractive index of the lens 174, the light emitted from the light-emitting diode De can be reflected, thereby decreasing the light efficiency. The refractive index of the control pattern 172, preferably, can be equal to or less than the refractive index of the passivation layer 170.

For example, the refractive index of the control pattern 172 can be 1.65 or greater and 1.8 or less, and the refractive index of the passivation layer 170 can be 1.8 or greater. However, embodiments of the present disclosure are not limited thereto.

The control pattern 172 can be formed of an inorganic insulating material. For example, the inorganic insulating material of the control pattern 172 can include silicon nitride (SiNₓ), silicon oxide (SiOₓ), or silicon oxynitride (SiON).

Alternatively, the control pattern 172 can be formed of an organic insulating material. For example, the organic insulating material of the control pattern 172 can include an acrylate polymer, a biphenyl polymer, a phenyl sulfide polymer, a diphenyl fluorine polymer, or a carbazole polymer.

In addition, the control pattern 172 can further include inorganic particles. For example, the inorganic particles can include zirconium dioxide (ZrO₂) and/or titanium dioxide (TiO₂). In this case, the inorganic particles can be in a core-shell form having a core of titanium dioxide (TiO₂) and a shell of zirconium dioxide (ZrO₂).

When the control pattern 172 is formed of an organic insulating material, it is preferable that the glass transition temperature Tg of the control pattern 172 be greater than the glass transition temperature Tg of the lens 174 so that the material of the control pattern 172 may not have fluidity even if the material of the lens 174 has fluidity.

Further, it is preferable that the surface energy of the control pattern 172 be equal to or less than the surface tension of the material of the lens 174. In this case, the surface energy of the control pattern 172 can be smaller than the surface energy of the passivation layer 170.

If the surface energy of the control pattern 172 is greater than the surface tension of the material of the lens 174, since the contact angle of the material of the lens 174 can be reduced during the reflow process, the shape of the lens 174 can be deformed.

The control pattern 172 can include a polymer that is formed by using the same material as the lens 174. In this case, the polymer of the control pattern 172 can have different molecular weight from the polymer of the lens 174.

The molecular weight can vary depending on a degree of cross-linking, and the degree of cross-linking can be controlled by adjusting a content ratio of the monomer and the initiator and/or an exposure dose and luminous intensity.

For example, the material of the control pattern 172 and the material of the lens 174 can include a binder, a monomer, an initiator, and other additives. The content of the initiator in the material of the control pattern 172 for the monomer can be greater than the content of the initiator in the material of the lens 174. Accordingly, the molecular weight of the polymer of the control pattern 172 can be greater than the molecular weight of the polymer of the lens 174. In addition, the glass transition temperature Tg of the polymer of the control pattern 172 can be greater than the glass transition temperature Tg of the polymer of the lens 174.

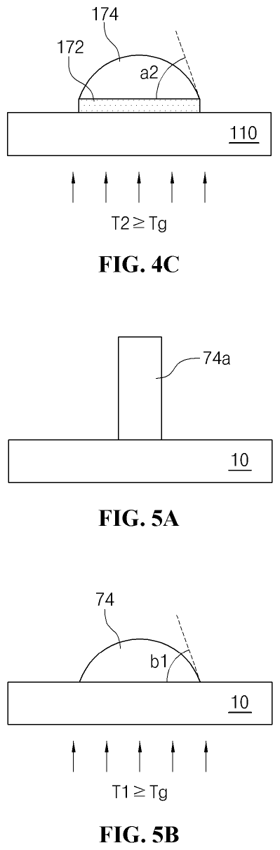

The formation and deformation prevention of the lens 174 using the control pattern 172 will be described in detail with reference to FIGS. 4A to 4C.

FIGS. 4A to 4C are schematic enlarged cross-sectional views of a display device in steps of forming a lens and a step of performing a reliability test according to the embodiment of the present disclosure.

As shown in FIG. 4A, the control pattern 172 having the step can be formed over the substrate 110. Although not shown in the figure, the plurality of layers described in FIG. 2 can be provided between the substrate 110 and the control pattern 172.

Then, a polymer pattern 174a can be formed over the control pattern 172 by applying an organic insulating material and patterning it through a photolithography process. At this time, the width of the polymer pattern 174a can be smaller than the width of the control pattern 172. The polymer pattern 174a may not be completely cured to have fluidity when heat is applied.

Next, as shown in FIG. 4B, the lens 174 can be formed by applying heat and reflowing the polymer pattern 174a.

Specifically, a first temperature T1 equal to or higher than the glass transition temperature Tg of the material of the polymer pattern 174a can be applied. Accordingly, the storage modulus and viscosity of the polymer pattern 174a can be reduced, so that the polymer pattern 174a can be changed into a liquid phase that can flow from a glassy phase, and the phase-changed polymer pattern 174a can be reflowed to have a specific contact angle a1 due to the difference in the surface energy with the control pattern 172 thereunder.

In this case, the phase-changed polymer pattern 174a can change into a shape close to a spherical shape having the minimum surface area in order to have the most stable state, thereby implementing the shape of the lens 174. Due to the step of the control pattern 172, the contact angle a1 can be created at the end of the step, that is, at the edge of the top surface of the control pattern 172, and the shape of the lens 174 can be maintained as the reflow of the horizontal direction changes to the vertical direction.

The lens 174 can have substantially the same width as the control pattern 172, and the contact angle a1 of the lens 174, that is, a first contact angle a1 can be 70 degrees to 80 degrees.

Next, as shown in FIG. 4C, the reliability test can be performed by exposing the lens 174 to a high temperature environment equal to or higher than the glass transition temperature Tg. That is, a second temperature T2 equal to or higher than the glass transition temperature Tg can be applied to the lens 174. At this time, the lens 174 can change into the liquid phase and have fluidity, and after responding to a change in the contact angle without a change in width by the control pattern 172, the lens 174 can return to the glassy phase, thereby having a second contact angle a2.

The second contact angle a2 of the lens 174 can be substantially the same as the first contact angle a1, and the deformation of the lens 174 in the high temperature environment can be suppressed by the control pattern 172. Accordingly, the reliability can be improved.

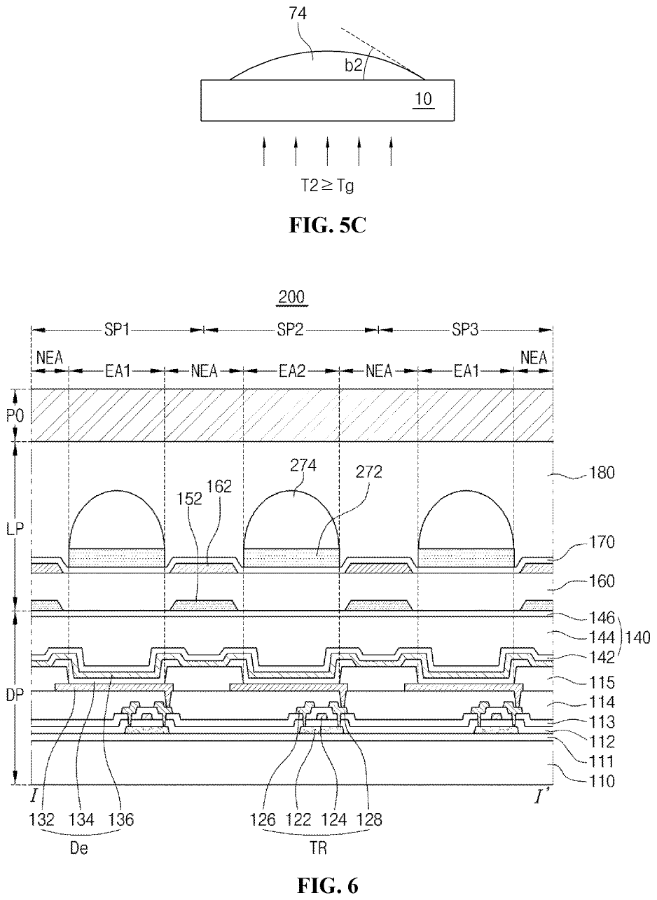

On the other hand, if the control pattern 172 is not provided, the shape of the lens 174 can vary depending on the position when the lens 174 is formed, and the shape of the lens 174 can be changed in the high temperature environment, thereby lowering reliability. This will be described with reference to FIGS. 5A to 5C.

FIGS. 5A to 5C are schematic enlarged cross-sectional views of a display device in steps of forming a lens and a step of performing a reliability test according to a comparative example.

As shown in FIG. 5A, in the display device according to the comparative example, a polymer pattern 74a can be formed over a substrate 10 by applying an organic insulating material and patterning it through a photolithography process.

Next, as shown in FIG. 5B, the lens 74 can be formed by applying heat and reflowing the polymer pattern 74a. That is, a first temperature T1 equal to or higher than the glass transition temperature Tg of the material of the polymer pattern 74a can be applied. In this case, the lens 74 can have a first contact angle b1, and the first contact angle b1 can be substantially the same as the first contact angle a1 of the lens 174 of FIG. 4B.

However, as described above, the first contact angle b1 of the lens 74 may not be uniform and can vary due to the variation in the molecular weight and the glass transition temperature Tg of the polymer pattern 74a depending on the position.

Next, as shown in FIG. 5C, the reliability test can be performed by exposing the lens 74 to a high temperature environment equal to or higher than the glass transition temperature Tg. That is, a second temperature T2 equal to or higher than the glass transition temperature Tg can be applied to the lens 74. At this time, the lens 74 can have fluidity, and the width and contact angle of the lens 74 can be changed. That is, the width of the lens 74 can be increased, and the contact angle of the lens 74 can be decreased.

The lens 74 can have a second contact angle b2, and the second contact angle b2 can be smaller than the first contact angle b1.

Accordingly, in the display device according to the comparative example, the shape of the lens 74 can be changed in the high temperature environment, thereby lowering the reliability.

As such, in the display device 100 according to the embodiment of the present disclosure, by providing the control pattern 172 under the lens 174 and limiting the contact angle and the reflow area of the material of the lens 174, the uniformity can be improved, and the reliability can be increased.

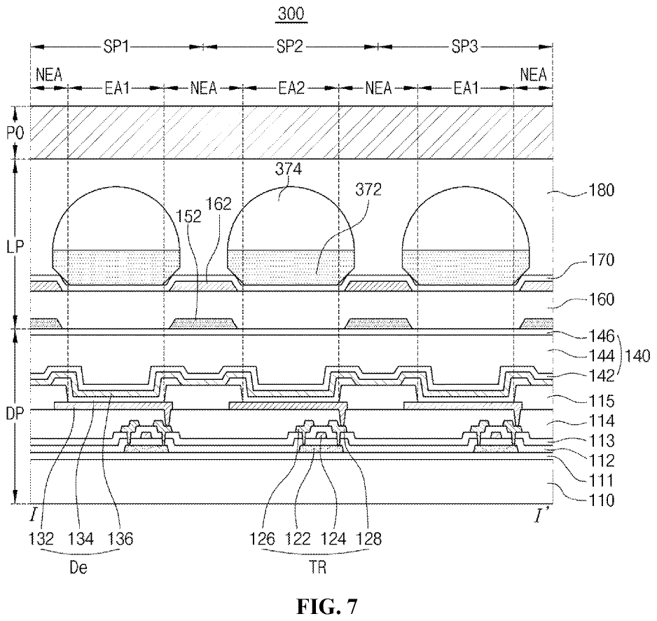

The control pattern 172 can be configured variously. That is, the shape and size of the control pattern 172 can vary. Display devices according to other embodiments of the present disclosure will be described with reference to FIGS. 6 and 7.

FIG. 6 is a schematic enlarged cross-sectional view of a display device according to another embodiment of the present disclosure, and FIG. 7 is a schematic enlarged cross-sectional view of a display device according to yet another embodiment of the present disclosure.

The display devices according to the other embodiments of the present disclosure have substantially the same configuration as that of the previous embodiment, except for the control pattern and the lens. The same parts as those of the previous embodiment are designated by the same or similar reference signs, and explanation for the same parts can be shortened or omitted.

As shown in FIGS. 6 and 7, in the display devices 200 and 300 according to the other embodiments of the present disclosure, the sensor layer 162 can be provided over the intermediate insulation layer 160, the passivation layer 170 can be provided over the sensor layer 162, and the control pattern 272 and 372 and the lens 274 and 374 can be sequentially provided over the passivation layer 170. The control pattern 272 and 372 and the lens 274 and 374 can be disposed to correspond to the emission area EA1 and EA2.

In the display device 200 according to another embodiment of the present disclosure of FIG. 6, the control pattern 272 and the lens 274 can be disposed only in the opening of the sensor layer 162 and may not overlap the sensor layer 162. In this case, the control pattern 272 and the lens 274 can be spaced apart from the sensor layer 162.

Alternatively, in the display device 300 according to yet another embodiment of the present disclosure of FIG. 7, the control pattern 372 and the lens 374 can overlap the sensor layer 162. In this case, a part of a side surface of the control pattern 372 can have a reverse inclination with respect to the substrate 110.

The control pattern 272 and 372 can increase a length of the side surface thereof compared to the control pattern 172 of FIG. 3, thereby increasing a distance between the lens 274 and 3744 and the passivation layer 170. Accordingly, it is possible to further prevent or reduce the shape deformation of the lens 274 and 374 in the high temperature environment.

In the display device of the present disclosure, by providing the light control panel including the lens and the light-blocking layer over the display panel, the front luminance can be increased, and the viewing angle can be limited.

Additionally, in the display device of the present disclosure, by providing the control pattern under the lens, the uniformity can be improved, and the deformation of the lens can be prevented or reduced in the high temperature environment.

Accordingly, the reliability can be improved, and the production power consumption can be reduced by improving the lifetime to thereby achieve the low power consumption.

Further, the size and shape of the control pattern can be variously applied, thereby increasing the degree of freedom of the process.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a substrate having an emission area and a non-emission area;
a thin film transistor over the substrate, wherein the thin film transistor comprises a gate electrode, an active layer, a source electrode, and a drain electrode;
a light-emitting diode in the emission area over the thin film transistor, wherein the light-emitting diode comprises a first electrode, a light-emitting layer, and a second electrode;
a bank in the non-emission area over the thin film transistor, wherein the bank is disposed between the first electrode and the light-emitting layer;
a control pattern over the light-emitting diode and the bank, wherein the control pattern corresponds to the emission area; and
a lens over the control pattern, wherein the lens corresponds to the emission area,
wherein the control pattern corresponds to the lens one-to-one and forms a step under the lens.

2. The display device of claim 1, wherein the control pattern and the lens overlap the bank.

3. The display device of claim 1, wherein a width and an area of the lens are equal to or less than a width and an area of the control pattern, respectively.

4. The display device of claim 1, further comprising a sensor layer between the light-emitting diode and the control pattern, wherein the sensor layer corresponds to the non-emission area.

5. The display device of claim 4, wherein the control pattern and the lens overlap the sensor layer.

6. The display device of claim 4, wherein the sensor layer comprises an opening corresponding to the emission area, and wherein the control pattern and the lens are disposed in the opening.

7. The display device of claim 4, wherein at least a part of a side surface of the control pattern comprises a reverse inclination with respect to the substrate.

8. The display device of claim 4, further comprising a black matrix between the light-emitting diode and the sensor layer, wherein the black matrix corresponds to the non-emission area.

9. The display device of claim 8, further comprising an intermediate insulating layer between the black matrix and the sensor layer.

10. The display device of claim 1, wherein a refractive index of the control pattern is equal to or greater than a refractive index of the lens.

11. The display device of claim 1, wherein a glass transition temperature of the control pattern is higher than a glass transition temperature of the lens.

12. The display device of claim 1, wherein the control pattern and the lens are formed of a same material, wherein each of the control pattern and the lens comprises a polymer, and wherein a polymer of the control pattern and a polymer of the lens have different molecular weights.

13. The display device of claim 12, wherein a molecular weight of the polymer of the control pattern is greater than a molecular weight of the polymer of the lens.

14. The display device of claim 12, wherein the control pattern comprises an acrylate polymer, a biphenyl polymer, a phenyl sulfide polymer, a diphenyl fluorine polymer, or a carbazole polymer.

15. The display device of claim 14, wherein the control pattern further comprises inorganic particles.

16. The display device of claim 15, wherein the inorganic particles comprise at least one of zirconium dioxide and titanium dioxide.

17. The display device of claim 16, wherein the inorganic particles are in a core-shell form having a core of titanium dioxide and a shell of zirconium dioxide.
